(19) United States
(12) Patent Application Publication
(10) Pub. No.: US 2024/0006189 A1
(43) Pub. Date: Jan. 4, 2024

(54) Chemical Mechanical Planarization (CMP) For Copper And Through-Silicon Via (TSV)

(71) Applicant: Versum Materials US, LLC, Tempe, AZ (US)

(72) Inventors: Xiaobo Shi, Chandler, AZ (US); Hongjun Zhou, Chandler, AZ (US); Robert Vacassy, Phoenix, AZ (US); Keh-Yeuan LI, Hsindian District (TW); Ming Shih Tsai, Zhudong Township (TW); Rung-Je Yang, Chiading District (TW)

(21) Appl. No.: 18/255,530

(22) PCT Filed: Dec. 7, 2021
(86) PCT No.: PCT/US21/72778

§ 371 Date: Jun. 1, 2023

Related U.S. Application Data
(60) Provisional application No. 63/124,997, filed on Dec. 14, 2020.

(51) Int. Cl. H01L 21/321; C09G 1/02; H01L 21/768; H01L 21/306

(52) U.S. Cl. CPC H01L 21/3212; C09G 1/02; H01L 21/76898; H01L 21/30625

(57) ABSTRACT

Provided are Chemical Mechanical Planarization (CMP) compositions that offer high and tunable Cu removal rates and low Cu static etching rates for polishing the broad bulk or advanced node copper or Through Silica Via (TSV). The CMP compositions also provide high selectivity of Cu film vs. other barrier layers, such as Ta, TaN, Ti, TiN, and SiN; and dielectric films, such as TEOS, low-k, and ultra-low-k films. The CMP polishing compositions comprise abrasive, oxidizer, at least two chelators selected from the group consisting of amino acids, amino acid derivatives, and combinations therefore; the Cu static etching reducing agents include, but not limited to, organic alkyl sulfonic acids with straight or branched alkyl chains, and salts of organic alkyl sulfonic acids.

### BACKGROUND OF THE INVENTION

This invention relates generally to the chemical-mechanical planarization or chemical-mechanical polishing (CMP) of semiconductor wafers. More specifically, present invention relates to high and tunable Cu film removal rates and low Cu static etching rates for the broad or advanced node copper and/or Through Silica Via (TSV) CMP applications.

Copper is the current material of choice for interconnect metal used in the fabrication of integrated electronic devices due to its low resistivity, high reliability, and scalability. Copper chemical mechanical planarization processes are necessary to remove copper overburden from inlaid trench structures while achieving global planarization with low metal loss.

With advancing technology nodes, the need to reduce metal loss becomes increasingly important. Any new polishing formulations need to maintain high removal rates, high selectivity to the barrier material and low defectivity, and low Cu static etching rates.

U.S. Pat. Nos. 8,586,481; 8,859,429; 8,877,644; 8,889,555; 20,080,254,628 reported Cu CMP polishing compositions which provided high Cu removal rates.

However, the disclosed polishing compositions were unable to meet the performance requirements.

Therefore, there are significant needs for CMP compositions, methods, and systems that can offer higher removal rate; at the same time achieving low Cu static etching rates to meet the challenging requirements for advanced technology nodes

### BRIEF SUMMARY OF THE INVENTION

Described herein are CMP polishing compositions, methods, and systems developed to meet challenging requirements in the advanced technology node.

CMP polishing compositions, CMP polishing formulations, or CMP polishing slurries are interchangeable in the present invention.

More specifically, the CMP polishing compositions are dual chelators based offering high Cu removal rate and low Cu static etch rate for Cu and TSV CMP applications.

In one aspect, the invention herein provides chemical mechanical polishing (CMP) composition for a copper bulk and Through Silica Via (TSV) comprises:
a) abrasive;
b) at least two chelators; and
c) oxidizing agent;
d) water;
e) at least one Cu static etching rate reducing agent;
optionally
f) corrosion inhibitor;
g) organic quaternary ammonium salt;
h) biocide; and
i) pH adjusting agent;

wherein
the at least two chelators are different and independently selected from the group consisting of amino acids, amino acid derivatives, and combinations therefor; and
the pH of the composition is from 3.0 to 12.0; from 4.0 to 9.0; from 5.0 to 9.0, or from 6.0 to 8.5.

In another aspect, the invention provides a method of chemical mechanical polishing a semiconductor substrate containing at least one copper or copper-containing surface, comprising steps of:
1) providing the semiconductor substrate;
2) providing a polish pad;
3) providing a chemical mechanical polishing composition comprising
a) abrasive;
b) oxidizing agent;
c) at least two chelators;
d) at least one Cu static etching rate reducing agent; and
e) water;
a. optionally
f) corrosion inhibitor;
g) organic quaternary ammonium salt;
h) biocide; and
i) pH adjusting agent;
wherein
   the at least two chelators are different and independently selected from the group consisting of amino acids, amino acid derivatives, and combinations therefor;
and the pH of the composition is from 3.0 to 12.0; from 4.0 to 9.0; from 5.0 to 9.0; or from 6.0 to 8.5;
contacting the semiconductor substrate with the polish pad and the chemical mechanical polishing composition; and
4) polishing the semiconductor substrate;
wherein at least one portion of the at least one copper or copper-containing surface is in contact with both the polishing pad and the chemical mechanical polishing composition.

In yet another aspect, the invention provides a method of a selective chemical mechanical polishing comprising steps of:
1) providing a semiconductor substrate having at least one surface containing a first material and at least one second material;
2) providing a polishing pad;
3) providing a chemical mechanical polishing composition comprising:
4) polishing the semiconductor substrate to selectively remove the first material;
   a) abrasive;
   b) oxidizing agent;
   c) at least two chelators;
   d) at least one Cu static etching rate reducing agent; and
   e) water;
   1. optionally
   f) corrosion inhibitor;
   g) organic quaternary ammonium salt;
   h) biocide; and
   i) pH adjusting agent;
   wherein
   the at least two chelators are different and independently selected from the group consisting of amino acids, amino acid derivatives, and combinations therefor; and the pH of the composition is from 3.0 to 12.0; from 4.0 to 9.0; from 5.0 to 9.0; or from 6.0 to 8.5;
   polishing the semiconductor substrate to selectively remove the first material;
wherein removal rate of the first material to removal rate of the second material is equal or greater than 500:1; 1000:1; or 3000:1; and
the first material is copper or copper containing material, and the second material is selected from the group consisting of barrier layer material such as Ta, TaN, Ti, TiN, and SiN film, or dielectric layer material such as TEOS, low-k, and ultra-low-k film.

In yet another aspect, the invention provides a system of chemical mechanical polishing a semiconductor substrate containing at least one copper or copper-containing surface, comprising
1) the semiconductor substrate;
2) a polish pad; and
3) a chemical mechanical polishing composition comprising
   a) abrasive;
   b) oxidizing agent;
   c) at least two chelators;
   d) at least one Cu static etching rate reducing agent; and
   e) water;
      optionally
   f) corrosion inhibitor;
   g) organic quaternary ammonium salt;
   h) biocide; and
   i) pH adjusting agent;
   wherein
   the at least two chelators are different and independently selected from the group consisting of amino acids, amino acid derivatives, and combinations therefor; and the pH of the composition is from 3.0 to 12.0; from 4.0 to 9.0; from 5.0 to 9.0; from 6.0 to 8.5; or from 6.0 to 8.5;
wherein at least one portion of the at least one copper or copper-containing surface is in contact with both the polishing pad and the chemical mechanical polishing composition.

The abrasive particles used include, but are not limited to, colloidal silica or high purity colloidal silica; the colloidal silica particles doped by other inorganic oxide within lattice of the colloidal silica, such as alumina doped silica particles; colloidal aluminum oxide including alpha-, beta-, and gamma-types of aluminum oxides; colloidal and photoactive titanium dioxide, cerium oxide, colloidal cerium oxide, nano-sized inorganic metal oxide particles, such as alumina, titania, zirconia, ceria etc.; nano-sized diamond particles, nano-sized silicon nitride particles; mono-modal, bi-modal, multi-modal colloidal abrasive particles; organic polymer-based soft abrasives, surface-coated or modified abrasives, or other composite particles, and mixtures thereof.

The corrosion inhibitors include but are not limited to family of hetero aromatic compounds containing nitrogen atom(s) in their aromatic rings, such as 1,2,4-triazole, 3-amino-1,2,4-triazole (or called amitrole), 3,5-diamino-1,2,4-triazole, 1,2,3-triazole, benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The biocide includes but is not limited to Kathon™, Kathon™ CG/ICP II, Neolone, Bioban, from Dow-Dupont. They have active ingredients of 5-chloro-2-methyl-4-isothiazolin-3-one and/or 2-methyl-4-isothiazolin-3-one.

The Cu static etching reducing agents include, but not limited to, organic alkyl sulfonic acids with straight or branched alkyl chains, or their ammonium, sodium, or potassium salts of organic alkyl sulfonate surface wetting agents. For examples, dodecyl sulfonic acid, dodecyl sulfonate, ammonium salt of dodecyl sulfonic acid (ammonium dodecyl sulfonate), potassium salt of dodecyl sulfonic acid (potassium dodecyl sulfonate), sodium salt of dodecyl sulfonic acid (sodium dodecyl sulfonate), 7-Ethyl-2-methyl-4-undecyl sulfate sodium salt (such as Niaproof®4), or sodium 2-ethylhexyl sulfate (such as Niaproof® 08).

The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof. Hydrogen peroxide is the preferred oxidizing agent.

The at least two chelators can be combinations of at least two amino acids, combinations of at least two amino acid derivatives, combinations of at least one amino acid with at least one amino acid derivative.

The amino acids and amino acid derivatives include, but not limited to, glycine, D-alanine, L-alanine, DL-alanine, bicine, tricine, sarcosine, beta-alanine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, and combinations thereof.

The organic quaternary ammonium salt includes but is not limited to choline salt, such as choline bicarbonate salt, or all other salts formed between choline and other anionic counter ions.

The choline salts can have the general molecular structures shown below:

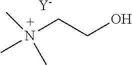

wherein anion Y⁻ can be bicarbonate, hydroxide, p-toluene-sulfonate, bitartrate, and other suitable anionic counter ions.

### BRIEF DESCRIPTION OF SEVERAL VIEWS OF THE DRAWINGS

FIG. 1: Effects of ADS on Cu Removal Rates & Cu Static Etching Rates

### DETAILED DESCRIPTION OF THE INVENTION

As industry standards trend toward smaller device features, there is a continuously developing need for new Cu and TSV bulk metal polishing slurries that afford high and tunable Cu removal rates and low Cu static etching rates for the broad and advanced node applications.

The copper bulk CMP or Through Silica Via (TSV) polishing compositions described herein satisfy the need for high and tunable Cu film removal rates, for high selectivity between copper and dielectric films, for high selectivity between copper and barrier films, for low Cu static etching rates, and for better Cu film corrosion protection through using the suitable corrosion inhibitors.

The CMP polishing compositions comprise abrasive;
a) oxidizing agent;
b) at least two chelators;
c) at least one Cu static etching rate reducing agent; and
d) water;
   optionally
e) corrosion inhibitor;
f) organic quaternary ammonium salt;
g) biocide; and
h) pH adjusting agent;
wherein
the at least two chelators are different and are independently selected from the group consisting of amino acids, amino acid derivatives, and combinations therefor; wherein at least one chelator is an amino acid or an amino acid derivative; and the pH of the composition is from 3.0 to 12.0; from 4.0 to 9.0; from 5.0 to 9.0; or from 6.0 to 8.5.

The Cu CMP polishing compositions provide high and tunable Cu removal rates, low Cu static etching rates, and low barrier film and dielectric film removal rates which provide very high and desirable selectivity of Cu film vs. other barrier films, such as Ta, TaN, Ti, TiN, and SiN; and/or dielectric films, such as TEOS, low-k, and ultra-low-k films.

The chemical mechanical polishing compositions also provide no pad stain Cu CMP performances which allow the extended polish pad life and also allow more stable end-point detections.

All percentages in the compositions are weight percentages unless otherwise indicated.

The abrasive particles used for the disclosed herein Cu bulk and TSV CMP polishing compositions include, but are not limited to, colloidal silica or high purity colloidal silica; the colloidal silica particles doped by other inorganic oxide within lattice of the colloidal silica, such as alumina doped silica particles; colloidal aluminum oxide including alpha-, beta-, and gamma-types of aluminum oxides; colloidal and photoactive titanium dioxide, cerium oxide, colloidal cerium oxide, nano-sized inorganic metal oxide particles, such as alumina, titania, zirconia, ceria etc.; nano-sized diamond particles, nano-sized silicon nitride particles; mono-modal, bi-modal, multi-modal colloidal abrasive particles; organic polymer-based soft abrasives, surface-coated or modified abrasives, or other composite particles, and mixtures thereof.

Preferred abrasive particles are colloidal silica and high purity colloidal silica. The colloidal silica can be made from silicate salts, the high purity colloidal silica can be made from TEOS or TMOS. The colloidal silica or high purity colloidal silica can have narrow or broad particle size distributions with mono-model or multi-models, various sizes and various shapes including spherical shape, cocoon shape, aggregate shape, and other shapes,

The nano-sized particles also can have different shapes, such as spherical, cocoon, aggregate, and others.

The particle size of the abrasives used in the Cu CMP slurries is ranged from 5 nm to 500 nm, from 10 nm to 250 nm, or from 25 nm to 100 nm.

The Cu bulk CMP polishing compositions of this invention preferably contain 0.0025 wt. % to 25 wt. %, from 0.0025 wt. % to 2.5 wt. %, or from 0.005 wt. % to 0.75 wt. % of abrasive.

The organic quaternary ammonium salt includes but is not limited to choline salt, such as choline bicarbonate salt, or all other salts formed between choline and other anionic counter ions.

The choline salts can have the general molecular structures shown below:

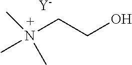

wherein anion Y⁻ can be bicarbonate, hydroxide, p-toluene-sulfonate, bitartrate, and other suitable anionic counter ions.

The CMP slurry contains 0.005 wt. % to 0.25 wt. %; 0.001 wt. % to 0.1 wt. %; or 0.002 wt. % to 0.05 wt. % quaternary ammonium salt.

Various per-oxy inorganic or organic oxidizing agents or other types of oxidizing agents can be used to oxidize the metallic copper film to the mixture of copper oxides to allow their quick reactions with chelating agents and corrosion inhibitors. The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof. The preferred oxidizer is hydrogen peroxide.

The CMP slurry contains 0.1 wt. % to 10 wt. %, 0.25 wt. % to 4.0 wt. %; or 0.5 wt. % to 3.0 wt. %. oxidizing agents.

The Cu static etching reducing agents include, but not limited to, organic alkyl sulfonic acids with straight or branched alkyl chains, or their ammonium, sodium, or potassium salts.

Examples include, but are not limited to, dodecyl sulfonic acid, ammonium salt of dodecyl sulfonate, potassium salt of dodecyl sulfonate, sodium salt, dodecyl sulfonate, 7-Ethyl-2-methyl-4-undecyl sulfate sodium salt (such as Niaproof®4), or sodium 2-ethylhexyl sulfate (such as Niaproof® 08).

For examples, dodecyl sulfonic acid, dodecyl sulfonate, ammonium salt of dodecyl sulfonic acid (ammonium dodecyl sulfonate), potassium salt of dodecyl sulfonic acid (potassium dodecyl sulfonate), sodium salt of dodecyl sulfonic acid (sodium dodecyl sulfonate), 7-Ethyl-2-methyl-4-undecyl sulfate sodium salt (such as Niaproof®4), or sodium 2-ethylhexyl sulfate (such as Niaproof® 08).

The CMP slurry contains 0.001 wt. % to 1.0 wt. %; 0.005 8 wt. % to 0.5 wt. %; or 0.01 wt. % to 0.25 wt. % Cu static etching rate reducing agent.

The CMP slurry contains 0.0001 wt. % to 0.05 wt. %; 0.0001 wt. % to 0.025 wt. %; or wt. % to 0.01 wt. % biocide.

Optionally, acidic, or basic compounds or pH adjusting agents can be used to allow pH of Cu bulk CMP polishing compositions being adjusted to the optimized pH value,

The pH adjusting agents include, but are not limited to, the following: nitric acid, hydrochloric acid, sulfuric acid, phosphoric acid, other inorganic or organic acids, and mixtures thereof. pH adjusting agents also include the basic pH adjusting agents, such as sodium hydride, potassium hydroxide, ammonium hydroxide, tetraalkyl ammonium hydroxide, organic amines, and other chemical reagents that are able to be used to adjust pH towards the more alkaline direction.

The CMP slurry contains 0 wt. % to 1 wt. %; 0.01 wt. % to 0.5 wt. %; or 0.1 wt. % to wt. % pH adjusting agent.

The pH of the composition is from 3.0 to 12.0; from 4.0 to 9.0; from 5.0 to 9.0; or from 6.0 to 8.5.

The CMP slurry contains 0.1 wt. % to 20 wt. %; 0.5 wt. % to 15 wt. %; or 2.0 wt. % to wt. % of at least two chelators.

The at least two chelators are different and are selected independently from the group consisting of amino acids, amino acid derivatives, and combinations thereof.

The amino acids and amino acid derivatives included, but not limited to, glycine, D-alanine, L-alanine, DL-alanine, beta-alanine, bicine, tricine, sarcosine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, etc.

The at least two chelators can be combinations of at least two amino acids, combinations of at least two amino acid derivatives, combinations of at least one amino acid with at least one amino acid derivative. As an example, the two chelators can be glycine and alanine, glycine and bicine, glycine and sarcosine, glycine and serine, alanine and bicine.

The at least two chelators used as complexing agents to maximize their reactions with the oxidized Cu film surfaces to form softer Cu-chelator layers to be quickly removed during Cu CMP process thus achieving high and tunable Cu removal rates for the broad or advanced node copper or TSV (Through Silica Via) CMP applications.

The use of dual chelators shows synergic effects on boosting Cu removal rates than the use of single chelator at same weight percentage.

The organic quaternary ammonium salt includes but is not limited to choline salt, such as choline bicarbonate salt, or all other salts formed between choline and other anionic counter ions.

The choline salts can have the general molecular structures shown below:

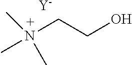

wherein anion Y⁻ can be bicarbonate, hydroxide, p-toluene-sulfonate, bitartrate, and other suitable anionic counter ions.

The associated methods and systems described herein entail use of the compositions for chemical mechanical planarization of substrates comprised of copper.

In the methods, a substrate, or a wafer, having Cu or Cu containing surface, or Cu plug is placed face-down on a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CMP processing while the platen and the substrate are rotated. The polishing composition (slurry) is applied (usually continuously) on the pad during CMP processing to affect the removal of material to planarize the substrate.

The polishing composition and associated methods as well as systems described herein are effective for CMP of a wide variety of substrates, including most of substrates having copper surfaces, or copper containing materials.

### EXPERIMENTAL SECTION

Polishing Pad Polishing pad, 101010 pad or Other polishing pad was used during Cu CMP, supplied by Dow Chemicals Company.
Biocides: All biocides were supplied by Dow-Dupont.
Chemical Additives: All other chemicals used in the polishing compositions were supplied by Sigma Aldrich.
Abrasives: High purity colloidal silica particles were supplied by Fuso Chemical Co. Ltd.

### Parameters

Å: angstrom(s)—a unit of length
BP: back pressure, in psi units
CMP: chemical mechanical planarization=chemical mechanical polishing
CS: carrier speed
DF: Down force: pressure applied during CMP, unit: psi
min: minute(s)
ml: milliliter(s)
mV: millivolt(s)
psi: pounds per square inch
PS: platen rotational speed of polishing tool, in rpm (revolution(s) per minute)
SF: polishing composition flow, ml/min
Removal Rates
Cu RR 1.0 psi Measured Copper removal rate at 1.0 psi down pressure of the CMP tool
Cu RR 1.5 psi Measured Copper removal rate at 1.5 psi down pressure of the CMP tool
Cu RR 2.5 psi Measured Copper removal rate at 2.5 psi down pressure of the CMP tool

### General Experimental Procedure

In the examples presented below, CMP experiments were run using the procedures and experimental conditions given below.

The CMP tool that was used in the examples is a 200 mm Mirra® polisher, or a 300 mm Reflexion Polisher, manufactured by Applied Materials, 3050 Boweres Avenue, Santa Clara, California, 95054.

An IC1010 pad or other type of polishing pad, supplied by Dow Chemicals Company was used on the platen for the blanket and Cu patterned wafer polishing studies. Pads were broken-in by polishing twenty-five dummy oxide (deposited by plasma enhanced CVD from a TEOS precursor, PETEOS) wafers. In order to qualify the tool settings and the pad break-in, two PETEOS monitors were polished with Syton® OX-K colloidal silica, supplied by Planarization Platform of Air Products Chemicals Inc. at baseline conditions.

Polishing experiments were conducted using blanket Cu wafers with 50K A thickness, Ta and SiN blanket wafers with 2500 Å thickness. The blanket wafers were purchased from Silicon Valley Microelectronics, 1150 Campbell Ave, CA, 95126.

### Working Examples

In this working example, there were reference slurries and testing slurries.

Reference 1 slurry (Ref. 1) contained about 7.5 wt. % (as 1.0X) single chelator glycine, 0.0154 wt. % (as 1X) of choline bicarbonate (CBC), 0.07502 wt. % (as 1X) of high purity colloidal silica, and 0.0001 wt. % of biocide, and with pH being adjusted to 7.2.

Reference 2 slurry (Ref. 2) contained about 7.5 wt. % (as 1.0X) single chelator bicine, wt. % (as 1X) of choline bicarbonate (CBC), 0.07502 wt. % (as 1X) of high purity colloidal silica, and 0.0001 wt. % of biocide, and with pH being adjusted to 7.2.

Reference 3 slurry (Ref. 3) contained about 7.5 wt. % (as 1.0X) single chelator sarcosine, 0.0154 wt. % (as 1X) of choline bicarbonate (CBC), 0.07502 wt. % (as 1X) of high purity colloidal silica, and 0.0001 wt. % of biocide, and with pH being adjusted to 7.2.

The working slurries contained 5.0 wt. % glycine (as 0.667X) as first chelator and contained 2.5 wt. % second chelator alanine (as 0.333X) (Slurry1); or 2.5 wt. % sarcosine (as (Slurry2); or 2.5 wt. % bicine (as 0.333X) (Slurry3), respectively.

All working slurries contained 0.0154 wt. % (as 1X) of choline bicarbonate (CBC), wt. % (as 1X) of high purity colloidal silica, and 0.0001 wt. % of biocide.

All slurries (reference and working slurries) used 2.0 wt. % of H₂O₂ as oxidizing agent at point of use, respectively. All slurries had a pH at 7.2 before the addition of hydrogen peroxide.

### Example 1

The polish testing results of using the Cu bulk CMP slurries containing dual chelators vs the reference samples which just used a single chelator in the polishing compositions were listed in Table 1.

TABLE 1
Cu Removal Rate Comparison in High Cu RR Bulk Slurries

| Slurry | Cu RR(Å/min.)@2.5 psi |
|---|---|
| Ref. 1 | 49555 |
| Ref. 2 | 2910 |
| Ref. 3 | 20921 |
| Slurry 1 | 49584 |
| Slurry 2 | 50420 |
| Slurry 3 | 52238 |

As the results shown in Table 1, Cu CMP slurries with dual chelators afforded higher Cu film removal rates at 2.5 psi down forces while comparing to the Cu removal rates obtained with slurries only using a single chelator at same wt. %.

The polish results of Cu removal rate using Cu bulk CMP slurries containing dual chelators vs the reference slurry which just used glycine as a single chelator in the slurry were listed in Table 2. The chelators had different concentrations as used in Table 1.

TABLE 2
Cu Removal Rate Comparison in High Cu RR Bulk Slurries

| | Cu RR(Å/ | Cu RR(Å/ |
|---|---|---|
| | min.)@2.5 | min.)@2.5 |
| Slurry | psi(93/87 RPM | psi 110/103 RPM |
| Ref.(1.25X Glycine) | 48873 | 49605 |
| Slurry (0.834X Glycine + | 49652 | 49693 |
| 0.416X Alanine) | | |
| Slurry (0.834X Glycine + | 52707 | 54189 |
| 0.416X Sarcosine) | | |
| Slurry (0.834X Glycine + | 53910 | 58268 |
| 0.416X Bicine) | | |

As the results shown in Table 2, Cu CMP polishing compositions with dual chelators afforded higher Cu film removal rates at 2.5 psi down forces while comparing to the Cu removal rates obtained with polishing composition only using glycine as single chelator at same total wt. %.

There were synergic effects on boosting Cu removal rates in glycine/sarcosine or glycine/bicine dual chelator based polishing compositions than only used glycine as single chelator in polishing composition.

The polishing rates for SiN and Ta using working slurries were 8 to 10 Å/min.; and 5 to 10 Å/min; respectively.

### Example 2

In this working example, reference slurry (Ref. 3) contained 9.06 wt. % single chelator glycine (as 1.25X), 0.0193 wt. % (as 1X) of choline bicarbonate (CBC), 0.09378 wt. % (as 1.25X) of high purity colloidal silica, and 0.000125 wt. % of biocide, and with pH being adjusted to 7.2.

Working slurries contained glycine and bicine as dual chelators with their wt. % ratios at 4:1, 2:1, and 1.14 to 1, and with total wt. % concentrations equal to the reference sample which used glycine as single chelator at 1.25X.

All slurries (reference and working slurries) used 2.0 wt. % of H₂O₂ as oxidizing agent at point of use, respectively. All slurries had a pH at 7.2 before the addition of hydrogen peroxide.

The Cu removal rate results were listed in Table 3.

TABLE 3
Cu Removal Rate Comparison in High Cu RR Bulk Slurries

| | Cu RR(Å/ | Cu RR(Å/ |
|---|---|---|
| | min.)@2.5 | min.)@2.5 |
| Slurry | psi(93/87 RPM | psi 110/103 RPM |
| Ref. (1.25X Glycine) | 48873 | 49605 |
| Slurry (Glycine:Bicine = 4:1) | 52384 | 54948 |
| Slurry (Glycine:Bicine = 2:1) | 53910 | 58268 |
| Slurry (Glycine:Bicine = 1.14:1) | 50117 | 53325 |

As the results shown in Table 3, Cu CMP slurries with dual chelators of glycine and bicine or glycine and sarcosine shown synergic effect on boosting Cu film removal rates and also offered higher Cu film removal rates at 2.5 psi down forces while comparing to the Cu removal rates obtained with reference slurry only using glycine as single chelator at same wt. %. Among three working examples, the highest Cu removal rate was achieved when the wt. % ratio of glycine to bicine is at 2:1.

### Example 3

In example 3, the effects of Cu static rate reducing agent ADS (ammonium dodecyl sulfonate) on Cu static etching rates and Cu removal rates were examined.

In this working example, reference slurry (Ref.) contained 7.5 wt. % (1X) concentrated single chelator glycine, 0.0154 wt. % (as 1X) of choline bicarbonate (CBC), 0.1892 wt. % (as 1X) amitrole as corrosion inhibitor, 0.07502 wt. % (as 1X) of high purity colloidal silica, and 0.0001 wt. % of biocide, and with pH being adjusted to 7.2.

In the first working sample (Slurry 1), 0.667X glycine and 0.333X alanine were used as dual chelators, 0.0154 wt. % (as 1X) of choline bicarbonate (CBC), 0.020 wt. % (as 0.132X) Amitrole used as corrosion inhibitor, 0.0120 wt. % ammonium dodecyl sulfonate (ADS) (as 1X) was used as Cu static etching rate reducing agent, 0.07502 wt. % (as 1X) of high purity colloidal silica, and 0.0001 wt. % of biocide, and with pH being adjusted to 7.2.

In the second working sample (Slurry 2), 0.667X glycine and 0.333X alanine were used as dual chelators, 0.0154 wt. % (as 1X) of choline bicarbonate (CBC), no Amitrole used as corrosion inhibitor, 0.0120 wt. % ADS (ammonium dodecyl sulfonate) was used as Cu static etching rate reducing agent, 0.06012 wt. % (as 1X) of high purity colloidal silica, and 0.0001 wt. % of biocide, and with pH being adjusted to 7.2.

In the third working sample (Slurry 3), 0.667X glycine and 0.333X alanine were used as dual chelators, 0.0154 wt. % (as 1X) of choline bicarbonate (CBC), 0.0250 wt. % (as 0.132X) Amitrole used as corrosion inhibitor, no ADS (ammonium dodecyl sulfonate) was used as Cu static etching rate reducing agent, 0.07502 wt. % (as 1X) of high purity colloidal silica, and 0.0001 wt. % of biocide, and with pH being adjusted to 7.2.

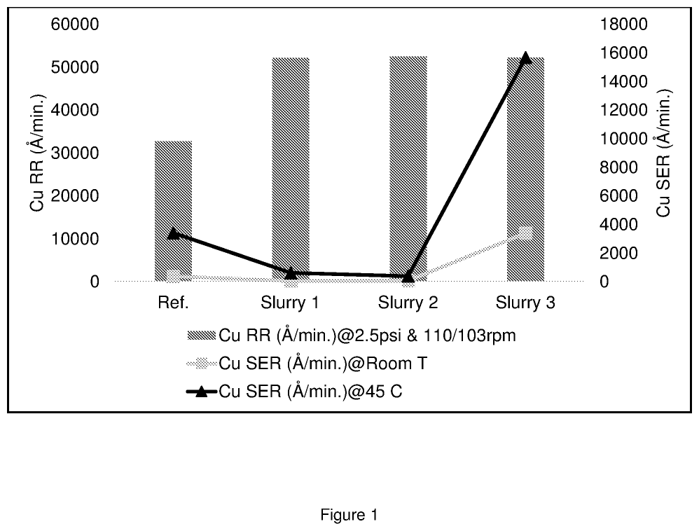

The results of the effects of ADS (ammonium dodecyl sulfonate) on Cu removal rates and Cu static etching rates were listed in Table 4 and depicted in FIG. 1.

TABLE 4
Effects of ADS on Cu Removal Rates & Cu Static Etching Rates

| | Cu RR (Å/ | | |
|---|---|---|---|
| | min.)@2.5 psi | Cu SER (Å/ | Cu SER (Å/ |
| Slurry | & 110/103 rpm | min.)@Room T | min.)@45 C. |
| Ref. | 32740 | 366 | 3397 |
| Slurry 1 | 52096 | 39.1 | 611.4 |
| Slurry 2 | 52423 | 55.5 | 387.2 |
| Slurry 3 | 52227 | 3396.5 | 15686.7 |

As the results shown in Table 4 and FIG. 1, Cu CMP polishing compositions with dual chelators of glycine and alanine at ratio of 2:1, very similar Cu film removal rates were obtained at 2.5 psi down force with or without using ADS as Cu static etching rare reducing agent, the Cu static etching rates were significantly reduced with the use of ADS (ammonium dodecyl sulfonate) as effective Cu static etching rate reducing agent.

### Example 4

The effects of pH conditions on Cu film removal rates were tested in the polishing compositions in Example 4 that contained 5.0 wt. % glycine (as 0.667X) as first chelator, and contained 2.5 wt. % alanine (as 0.333X) as second chelator plus 0.0154 wt. % (as 1X) of choline bicarbonate (CBC), 0.07502 wt. % (as 1X) of high purity colloidal silica, and 0.0001 wt. % of biocide, and with pH being adjusted respectively to 6.2, 7.2 and 8.2 prior to the addition of 2.5 wt. % hydrogen peroxide.

The polishing results on the effects of pH on Cu removal rates were listed in Table 5.

TABLE 5
Effects of pH Conditions on Cu Removal
Rates (A/min.) at 2.5 psi DF

| | Cu RR (Å/min.)@2.5 |
|---|---|
| Compositions | psi & 110/103 rpm |
| 0.667X Gly + 0.333X Ala, pH 6.2 | 54063 |
| pH 7.2 | 55096 |
| pH 8.2 | 49540 |

As the results shown in Table 5, Cu CMP polishing compositions with dual chelators of glycine and alanine at ratio of 2:1 and with 2.5 wt. % H₂O₂ as oxidizing agent, the highest Cu film removal rates were obtained at 2.5 psi down force under pH 7.2 condition, the lowest Cu film removal rates were obtained under pH 8.2 condition, but still high. At the pH conditions being tested, the invented herein Cu polishing composition with dual chelating agents afforded the high Cu removal rates at relative lower applied down force.

### Example 5

In Example 5, the effects of various Cu corrosion inhibitors on Cu film removal rates were tested vs the reference sample without using any Cu corrosion inhibitor in the glycine and alanine based dual chelator polishing composition with 2:1 ratio at 0.667X glycine and 0.333X alanine concentrations.

In the reference sample, 0.667X glycine and 0.333X alanine were used as dual chelators, 0.0154 wt. % (as 1X) of choline bicarbonate (CBC), no corrosion inhibitor being used, 0.0120 wt. % ADS (ammonium dodecyl sulfonate) was used as Cu static etching rate reducing agent, 0.06012 wt. % (as 1X) of high purity colloidal silica, and 0.0001 wt. % of biocide, and with pH being adjusted to 7.2.

In the first working sample, 0.667X glycine and 0.333X alanine were used as dual chelators, 0.0154 wt. % (as 1X) of choline bicarbonate (CBC), 0.0250 wt. % (as 0.132X) Amitrole was used as corrosion inhibitor, 0.0120 wt. % ADS (ammonium dodecyl sulfonate) (as 1X) was used as Cu static etching rate reducing agent, 0.06012 wt. % (as 1X) of high purity colloidal silica, and 0.0001 wt. % of biocide, and with pH being adjusted to 7.2.

In the second working sample, 0.667X glycine and 0.333X alanine were used as dual chelators, 0.0154 wt. % (as 1X) of choline bicarbonate (CBC), 0.0250 wt. % (as 0.132X) 2-aminobenzimidazole was used as corrosion inhibitor, 0.0120 wt. % ADS (ammonium dodecyl sulfonate) was used as Cu static etching rate reducing agent, 0.06012 wt. % (as 1X) of high purity colloidal silica, and 0.0001 wt. % of biocide, and with pH being adjusted to 7.2.

In the third working sample, 0.667X glycine and 0.333X alanine were used as dual chelators, 0.0154 wt. % (as 1X) of choline bicarbonate (CBC), 0.0250 wt. % (as 0.132X) Imidazole was used as corrosion inhibitor, 0.0120 wt. % ADS (ammonium dodecyl sulfonate) was used as Cu static etching rate reducing agent, 0.06012 wt. % (as 1X) of high purity colloidal silica, and 0.0001 wt. % of biocide, and with pH being adjusted to 7.2.

All reference and testing samples used 2.5 wt. % H₂O₂ as oxidizing agent.

The results of the effects of different Cu corrosion inhibitors on Cu removal rates were listed in Table 6.

TABLE 6
Effects of Cu Corrosion Inhibitors on
Cu Removal Rates (A/min.) at 2.5 psi DF

| | Cu RR (Å/min.)@2.5 |
|---|---|
| Compositions | psi & 110/103 rpm |
| Ref. No Corrosion Inhibitor | 52423 |
| Ref. + 0.132x Amitrole | 51492 |
| Ref. + 0.132x 2-amino-benzimidazole | 54647 |
| Ref. + 0.132x Imidazole | 55682 |

As the results shown in Table 6, Cu CMP polishing compositions with dual chelators of glycine and alanine at ratio of 2:1 and with 2.5 wt. % H₂O₂ as oxidizing agent, 0.132× amitrole as Cu corrosion inhibitor, the Cu removal rate was slightly reduced compared to the Cu removal rate from the reference sample without using any Cu corrosion inhibitor. When 0.132×2-amino-benzimidazole was used as Cu corrosion inhibitor, the Cu removal rate was increased compared to the Cu removal rate from the reference sample without using any Cu corrosion inhibitor. When 0.132× imidazole was used as Cu corrosion inhibitor, the Cu removal rate was increased by more than 6.0% compared to the Cu removal rate obtained from the reference sample without using any Cu corrosion inhibitor.

### Example 6

In Example 6, the effects of filtrations of Cu polishing compositions on Cu film removal rates were tested vs the reference sample without using filtration treatment on the glycine and alanine based dual chelator polishing composition with 2:1 ratio at 0.667X glycine and 0.333X alanine concentrations, 0.0120 wt. % (1X) ADS was used as Cu static etching rate reducing agent, 0.06012 wt. % (as 1X) high purity colloidal silica, and with 0.132x amitrole as corrosion inhibitor at pH 7.2.

The filtration process to filter the Cu polishing composition used 1.0+0.3 micron sized filters.

The results of the effects of filtrations of Cu polishing compositions on Cu film removal rates were listed in Table 7.

TABLE 7
Effects of Filtration on Cu Removal Rates (A/min.) at 2.5 psi DF

| | Cu RR (Å/min.)@2.5 |
|---|---|
| Compositions | psi & 110/103 rpm |
| 0.667X Gly + 0.333X Ala + | 52105 |
| 0.132x Amitrole w Filtration | |
| without filtration | 51868 |

As the results shown in Table 7, the filtration process using two different sized filters almost has no impacts on the Cu removal rates. Both filtered and unfiltered dual chelator based Cu polishing compositions provided high Cu removal rates at 2.5 psi applied down forces.

Afore listed Cu removal rate and Cu static etching rate testing results in the invented polishing compositions herein using selected dual chelators and ADS type Cu static etching reducing agents provided Cu bulk CMP slurries for bulk Cu and TSV CMP applications with high Cu removal rates and low CU static etching rates which satisfy the needs of advanced node Cu and TSV CMP applications.

While the invention has been described in conjunction with specific embodiments thereof, it is evident that many alternatives, modifications, and variations will be apparent to those skilled in the art in light of the foregoing description. Accordingly, departures may be made from such details without departing from the spirit or scope of the general inventive concept.

1. A chemical mechanical polishing composition for a copper bulk and Through Silica Via (TSV) comprises:
a) abrasive;
b) at least two chelators; and
c) oxidizing agent;
d) at least one Cu static etching rate reducing agent;
e) water;
optionally
f) corrosion inhibitor selected from the group consisting of hetero aromatic compounds containing nitrogen atom in their aromatic rings;
g) organic quaternary ammonium salt;
h) biocide; and
i) pH adjusting agent;
wherein
the at least two chelators are different chelators and independently selected from the group consisting of amino acids, amino acid derivatives, and combinations therefor;
the at least one Cu static etching rate reducing agent is an organic alkyl sulfonic acid with straight or branched alkyl chains, and its salts thereof; and
pH of the composition is from 4.0 to 9.0.

2. The chemical mechanical polishing composition of claim 1, wherein the abrasive is selected from the group consisting of colloidal silica; colloidal silica particles doped by other inorganic oxide within lattice of the colloidal silica; colloidal aluminum oxide including alpha-, beta-, and gamma-types of aluminum oxides; colloidal and photoactive titanium dioxide; cerium oxide; colloidal cerium oxide; alumina; titania; zirconia; ceria; nano-sized diamond particles; nano-sized silicon nitride particles; mono-modal, bi-modal, multi-modal colloidal abrasive particles; organic polymer-based soft abrasives; surface-coated or modified abrasives; and combinations thereof;
the at least two chelators are different and are independently selected from the group consisting of glycine, D-alanine, L-alanine, DL-alanine, beta-alanine, bicine, tricine, sarcosine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, and combinations thereof;
the oxidizing agent is selected from the group consisting of periodic acid, hydrogen peroxide, potassium iodate, potassium permanganate, ammonium persulfate, ammonium molybdate, ferric nitrate, nitric acid, potassium nitrate, and combinations thereof; and
the at least one Cu static etching rate reducing agent is selected from the group consisting of dodecyl sulfonic acid, dodecyl sulfonate, ammonium dodecyl sulfonate, potassium dodecyl sulfonate, sodium dodecyl sulfonate, and combinations thereof.

3. The chemical mechanical polishing composition of claim 1, wherein the abrasive is selected from the group consisting of colloidal silica; colloidal silica particles doped by other inorganic oxide within lattice of the colloidal silica; cerium oxide; colloidal cerium oxide; alumina; titania; zirconia; and combinations thereof;
the at least two chelators are different and are independently selected from the group consisting of glycine, D-alanine, L-alanine, DL-alanine, bicine, tricine, sarcosine, and combinations thereof;
the oxidizing agent is selected from the group consisting of periodic acid, hydrogen peroxide, potassium iodate, potassium permanganate, ammonium persulfate, ammonium molybdate, ferric nitrate, nitric acid, potassium nitrate, and combinations thereof;
and
the at least one Cu static etching rate reducing agent is selected from the group consisting of dodecyl sulfonate, ammonium dodecyl sulfonate, potassium dodecyl sulfonate, sodium dodecyl sulfonate, and combinations thereof.

4. The chemical mechanical polishing composition of claim 1, wherein the abrasive is colloidal silica; the at least two chelators are different and are independently selected from the group consisting of glycine, alanine, bicine, sarcosine, and combinations thereof; the oxidizing agent is hydrogen peroxide; and the at least one Cu static etching rate reducing agent is selected from the group consisting of ammonium dodecyl sulfonate, potassium dodecyl sulfonate, sodium dodecyl sulfonate, and combinations thereof.

5. (canceled)

6. (canceled)

7. (canceled)

8. (canceled)

9. (canceled)

10. (canceled)

11. (canceled)

12. (canceled)

13. The chemical mechanical polishing composition of claim 1, wherein the corrosion inhibitor is selected from the group consisting of 1,2,4-triazole, amitrole (or called 3-amino-1,2,4-triazole), 3,5-dimino-1,2,4-triazole, benzotriazole or benzotriazole derivatives, tetrazole or tetrazole derivatives, imidazole or imidazole derivatives, benzimidazole or benzimidazole derivatives, pyrazole or pyrazole derivatives, tetrazole or tetrazole derivatives, and combinations thereof; the organic quaternary ammonium salt is a choline salt having a general molecular structure of: 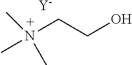
wherein anion Y⁻ is selected from the group consisting of bicarbonate, hydroxide, p-toluene-sulfonate, bitartrate, and combinations thereof;
the biocide comprises active ingredient selected from the group consisting of 5-chloro-2-methyl-4-isothiazolin-3-one, 2-methyl-4-isothiazolin-3-one, and combinations thereof; and the pH adjusting agent is selected from the group consisting of nitric acid, hydrochloric acid, sulfuric acid, phosphoric acid, other inorganic or organic acids, and combinations thereof; or the pH adjusting agent is selected from the group consisting of sodium hydride, potassium hydroxide, ammonium hydroxide, tetraalkyl ammonium hydroxide, organic amines, and combinations thereof.

14. (canceled)

15. (canceled)

16. (canceled)

17. (canceled)

18. (canceled)

19. (canceled)

20. The chemical mechanical polishing composition of claim 1, wherein the chemical mechanical polishing composition comprises colloidal silica; at least two different amino acids independently selected from the group consisting glycine, alanine, bicine, sarcosine, and combinations thereof; at least one Cu static etching rate reducing agent is ammonium dodecyl sulfonate, potassium dodecyl sulfonate, sodium dodecyl sulfonate, and combinations thereof; hydrogen peroxide; and the pH of the chemical mechanical polishing composition is from 5.0 to 9.0.

21. The chemical mechanical polishing composition of claim 1, wherein the chemical mechanical polishing composition comprises colloidal silica; at least two different amino acids independently selected from the group consisting glycine, alanine, bicine, sarcosine, and combinations thereof; a corrosion inhibitor selected from the group consisting of amitrole, 2-amino-benzimidazole, imidazole, and combinations thereof; at least one Cu static etching rate reducing agent is selected from the group consisting of ammonium dodecyl sulfonate, potassium dodecyl sulfonate, sodium dodecyl sulfonate, and combinations thereof; a choline bicarbonate salt; hydrogen peroxide; and the pH of the chemical mechanical polishing composition is from 5.0 to 9.0.

22. The chemical mechanical polishing composition of claim 1, wherein the chemical mechanical polishing composition comprises colloidal silica; at least two different amino acids independently selected from the group consisting glycine, alanine, bicine, sarcosine, and combinations thereof; at least one Cu static etching rate reducing agent is selected from the group consisting of ammonium dodecyl sulfonate, potassium dodecyl sulfonate, sodium dodecyl sulfonate, and combinations thereof; hydrogen peroxide; and the pH of the chemical mechanical polishing composition is from 6.0 to 8.5.

23. The chemical mechanical polishing composition of claim 1, wherein the chemical mechanical polishing composition comprises colloidal silica; at least two different amino acids independently selected from the group consisting glycine, alanine, bicine, sarcosine, and combinations thereof; a corrosion inhibitor selected from the group consisting of amitrole, 2-amino-benzimidazole, imidazole, and combinations thereof; at least one Cu static etching rate reducing agent is selected from the group consisting of ammonium dodecyl sulfonate, potassium dodecyl sulfonate, sodium dodecyl sulfonate, and combinations thereof; a choline bicarbonate salt; hydrogen peroxide; and the pH of the chemical mechanical polishing composition is from 6.0 to 8.5.

24. A method of chemical mechanical polishing a semiconductor substrate containing at least one copper or copper-containing surface, comprising steps of:
a) providing the semiconductor substrate;
b) providing a polish pad;
c) providing a chemical mechanical polishing composition comprising:
1) abrasive;
2) at least two chelators; and
3) oxidizing agent;
4) at least one Cu static etching rate reducing agent;
5) water;
optionally
6) corrosion inhibitor selected from the group consisting of hetero aromatic compounds containing nitrogen atom in their aromatic rings;
7) organic quaternary ammonium salt;
8) biocide; and
9) pH adjusting agent;
wherein
the at least two chelators are different chelators and independently selected from the group consisting of amino acids, amino acid derivatives, and combinations therefor;
the at least one Cu static etching rate reducing agent is an organic alkyl sulfonic acid with straight or branched alkyl chains, and its salts thereof; and
pH of the composition is from 4.0 to 9.0;
d) contacting the semiconductor substrate with the polish pad and the chemical mechanical polishing composition; and
e) polishing the semiconductor substrate;
wherein at least one portion of the at least one copper or copper-containing surface is in contact with both the polishing pad and the chemical mechanical polishing composition.

25. A method of chemical mechanical polishing a semiconductor substrate containing a first material and a second material, comprising steps of:
a) providing a semiconductor substrate having at least one surface containing a first material and at least one second material;
b) providing a polishing pad;
c) providing the chemical mechanical polishing composition according to claim 1;
d) polishing the semiconductor substrate to selectively remove the first material;
wherein removal rate of the first material to removal rate of the second material is equal or greater than 500:1; 1000:1; or 3000:1; and
the first material comprises copper and the second material is selected from the group consisting of barrier layer material selected from the group consisting of Ta, TaN, Ti, TiN, SiN, and combinations thereof; dielectric layer material selected from the group consisting of TEOS, low-k, ultra-low-k, and combinations thereof.

26. A system of chemical mechanical polishing a semiconductor substrate containing at least one copper or copper-containing surface, comprising
1) the semiconductor substrate;
2) a polish pad; and
f) a chemical mechanical polishing composition comprising:
1) abrasive;
2) at least two chelators; and
3) oxidizing agent;
4) at least one Cu static etching rate reducing agent;
5) water;
optionally
6) corrosion inhibitor selected from the group consisting of hetero aromatic compounds containing nitrogen atom in their aromatic rings;
7) organic quaternary ammonium salt;
8) biocide; and
9) pH adjusting agent;
wherein
the at least two chelators are different chelators and independently selected from the group consisting of amino acids, amino acid derivatives, and combinations therefor;
the at least one Cu static etching rate reducing agent is an organic alkyl sulfonic acid with straight or branched alkyl chains, and its salts thereof; and
pH of the composition is from 4.0 to 9.0;
wherein at least one portion of the at least one copper or copper-containing surface is in contact with both the polishing pad and the chemical mechanical polishing composition.

27. The method of chemical mechanical polishing of claim 24; wherein the chemical mechanical polishing composition comprises:
the abrasive selected from the group consisting of colloidal silica; colloidal silica particles doped by other inorganic oxide within lattice of the colloidal silica; colloidal aluminum oxide including alpha-, beta-, and gamma-types of aluminum oxides; colloidal and photoactive titanium dioxide; cerium oxide; colloidal cerium oxide; alumina; titania; zirconia; ceria; nano-sized diamond particles; nano-sized silicon nitride particles; mono-modal, bi-modal, multi-modal colloidal abrasive particles; organic polymer-based soft abrasives; surface-coated or modified abrasives; and combinations thereof;
the at least two chelators independently selected from the group consisting of glycine, D-alanine, L-alanine, DL-alanine, beta-alanine, bicine, tricine, sarcosine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, and combinations thereof;
the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and
the at least one Cu static etching rate reducing agent selected from the group consisting of dodecyl sulfonic acid, dodecyl sulfonate, ammonium dodecyl sulfonate, potassium dodecyl sulfonate, sodium dodecyl sulfonate, and combinations thereof.

28. The method of chemical mechanical polishing of claim 24; wherein the chemical mechanical polishing composition comprises:
the abrasive selected from the group consisting of colloidal silica; colloidal silica particles doped by other inorganic oxide within lattice of the colloidal silica; cerium oxide; colloidal cerium oxide; alumina; titania; zirconia; and combinations thereof;
the at least two chelators independently selected from the group consisting of glycine, D-alanine, L-alanine, DL-alanine, bicine, tricine, sarcosine, and combinations thereof;
the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and
the at least one Cu static etching rate reducing agent selected from the group consisting of dodecyl sulfonate, ammonium dodecyl sulfonate, potassium dodecyl sulfonate, sodium dodecyl sulfonate, and combinations thereof.

29. The method of chemical mechanical polishing of claim 24; wherein the chemical mechanical polishing composition comprises:
colloidal silica as the abrasive; the at least two chelators independently selected from the group consisting of glycine, alanine, bicine, sarcosine, and combinations thereof;
hydrogen peroxide as the oxidizing agent; ammonium dodecyl sulfonate as the at least one Cu static etching rate reducing agent.

30. The method of chemical mechanical polishing of claim 24; wherein the chemical mechanical polishing composition comprises colloidal silica as the abrasive; at least two different amino acids independently selected from the group consisting glycine, alanine, bicine, sarcosine, and combinations thereof; hydrogen peroxide as the oxidizing agent; ammonium dodecyl sulfonate as the at least one Cu static etching rate reducing agent; a corrosion inhibitor selected from the group consisting of amitrole, 2-amino-benzimidazole, imidazole, and combinations thereof; and a choline bicarbonate salt as the organic quaternary ammonium salt.

31. The system of chemical mechanical polishing of claim 26; wherein the chemical mechanical polishing composition comprises:
the abrasive selected from the group consisting of colloidal silica; colloidal silica particles doped by other inorganic oxide within lattice of the colloidal silica; colloidal aluminum oxide including alpha-, beta-, and gamma-types of aluminum oxides; colloidal and photoactive titanium dioxide; cerium oxide; colloidal cerium oxide; alumina; titania; zirconia; ceria; nano-sized diamond particles; nano-sized silicon nitride particles; mono-modal, bi-modal, multi-modal colloidal abrasive particles; organic polymer-based soft abrasives; surface-coated or modified abrasives; and combinations thereof;
the at least two chelators independently selected from the group consisting of glycine, D-alanine, L-alanine, DL-alanine, beta-alanine, bicine, tricine, sarcosine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, and combinations thereof;
the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and
the at least one Cu static etching rate reducing agent selected from the group consisting of dodecyl sulfonic acid, dodecyl sulfonate, ammonium dodecyl sulfonate, potassium dodecyl sulfonate, sodium dodecyl sulfonate, and combinations thereof.

32. The system of chemical mechanical polishing of claim 26; wherein the chemical mechanical polishing composition comprises:
the abrasive selected from the group consisting of colloidal silica, colloidal silica particles doped by other inorganic oxide within lattice of the colloidal silica, cerium oxide, colloidal cerium oxide, alumina, titania, zirconia, and combinations thereof;
the at least two chelators independently selected from the group consisting of glycine, D-alanine, L-alanine, DL-alanine, bicine, tricine, sarcosine, and combinations thereof;
the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and
the at least one Cu static etching rate reducing agent selected from the group consisting of dodecyl sulfonate, ammonium dodecyl sulfonate, potassium dodecyl sulfonate, sodium dodecyl sulfonate, and combinations thereof.

33. The system of chemical mechanical polishing of claim 26; wherein the chemical mechanical polishing composition comprises colloidal silica as the abrasive; the at least two chelators independently selected from the group consisting of glycine, alanine, bicine, sarcosine, and combinations thereof; hydrogen peroxide as the oxidizing agent; and ammonium dodecyl sulfonate as the at least one Cu static etching rate reducing agent.

34. The system of chemical mechanical polishing of claim 26; wherein the chemical mechanical polishing composition comprises colloidal silica as the abrasive; at least two different amino acids independently selected from the group consisting glycine, alanine, bicine, sarcosine, and combinations thereof; hydrogen peroxide as the oxidizing agent; ammonium dodecyl sulfonate as the at least one Cu static etching rate reducing agent; a corrosion inhibitor selected from the group consisting of amitrole, 2-amino-benzimidazole, imidazole, and combinations thereof; and a choline bicarbonate salt as the organic quaternary ammonium salt.
